(19) United States
(12) Patent Application Publication
(10) Pub. No.: US 2005/0270064 A1
(43) Pub. Date: Dec. 8, 2005

(54) Semiconductor device

(75) Inventors: Fumiki Kawakami, Akishima (JP); Naoki Yada, Tokorozawa (JP)

Correspondence Address: MILES & STOCKBRIDGE PC, 1751 PINNACLE DRIVE, SUITE 500, MCLEAN, VA, 22102-3833, US

(73) Assignee: Renesas Technology Corp.

(21) Appl. No.: 11/132,254

(22) Filed: May 19, 2005

(30) Foreign Application Priority Data
Jun. 7, 2004 (JP) 2004-168127
Mar. 1, 2005 (JP) 2005-55707

(51) Int. Cl. H03K 19/02

(52) U.S. Cl. 326/57

(57) ABSTRACT

An I/O buffer section is provided with a status setting circuit. The status setting circuit arbitrarily sets a signal state of an I/O terminal according to a combination of control signals stored in a setting register. Thus, the I/O buffer section is temporarily set to a Hi-Z state by the status setting circuit even in the case of the I/O terminal originally set to a signal holding state. Consequently, a leak test for testing whether the I/O buffer section is good or bad, can be performed, and the reliability of a semiconductor device can be enhanced.

### CROSS-REFERENCE TO RELATED APPLICATION

The present application claims priority from Japanese patent application No. 2004-168127 filed on Jun. 7, 2004, and Japanese patent application No. 2005-55707 filed on Mar. 1, 2005 the contents of which are hereby incorporated by reference into this application.

### BACKGROUND OF THE INVENTION

The present invention relates to a technique for setting a signal state of an I/O (Input/Output) buffer, and particularly to a technique effective when applied to a reduction in through current in an I/O buffer.

As each I/O buffer provided in a semiconductor device, there is known one wherein any of a pull-up circuit, a pull-down circuit, and a keeper circuit is provided to prevent a floating-based through current or the like of an input buffer for an unused I/O terminal.

The I/O buffers are constructed such that their circuit configurations become different according to the functions of I/O terminals. In brief, since there is a need to set a signal state of each I/O terminal at the design/manufacturing stage of the semiconductor device, the pull-up circuit is a circuit for bringing the I/O terminal to a pull-up state, and the pull-down circuit is a circuit for bringing the I/O terminal to a pull-down state. The keeper circuit is a circuit for holding a final input/output state of the I/O buffer.

In the semiconductor device, progress in reduction of an operating voltage has recently been made with miniaturization thereof. In an internal logic such as a CPU, it operates at an internal power supply voltage VDD of, for example, approximately 1.9V.

In the control field or the like of automobile equipment, a power supply voltage VCC of about 5V is generally widely used. Therefore, the low-voltage operated semiconductor device is internally provided with a step-down circuit. The step-down circuit steps down a power supply voltage VCC supplied from outside and supplies it as an internal power supply voltage VDD.

Thus, since each signal based on the same voltage level as the power supply voltage VCC is inputted from and outputted to the outside in the semiconductor device in which its internal logic circuit is operated at the internal power supply voltage VDD corresponding to the voltage lower than the externally-supplied power supply voltage VCC, a level converting circuit for performing the transfer of signals different in voltage level is provided therein.

The present level converting circuit is provided in, for example, a stage subsequent to an I/O buffer, and the like (disposed on the internal logic side). A level converting circuit is provided which converts a signal having a power supply voltage VCC amplitude to a signal having an internal power supply voltage VDD amplitude.

### SUMMARY OF THE INVENTION

However, it has been found out by the present inventors that the above semiconductor device involves the following problems.

In the technique of preventing a through current flowing in each I/O buffer (Input/Output buffer), the states of various signals are set every I/O terminals according to customer's specs or the like of the semiconductor device. When, for example, all of a pull-up state, a pull-down state and a keep state are required, it is necessary to prepare all of an I/O buffer provided with a pull-up circuit, an I/O buffer provided with a pull-down circuit and an I/O buffer provided with a keeper circuit. Therefore, a problem arises in that the variety of the I/O buffers that need preparations for individual semiconductor devices increases and hence the cost for design of each semiconductor device and the number of man-hours therefor, and the like increase.

There is also a case in which the settings of signal states of I/O terminals differ according to specs even in the case of the same variety of semiconductor devices. Consequently, a change in I/O buffer dependent on the specs, a change in design layout incident to it, etc. occur, thus causing a fear that the efficiency of design of the semiconductor device is degraded.

Further, a problem arises in that since the I/O buffer provided with the keeper circuit cannot be brought to a high impedance (Hi-Z) state, a current leak test on the I/O buffer cannot be performed upon, for example, a screening test or the like on the semiconductor device.

A configuration in which in the level converting circuit, two circuits in which P channel and N channel MOS transistors are connected in series, are respectively connected in a crossed form, has widely been known.

In this case, the P channel MOS transistor is driven by the power supply voltage VCC, whereas the N channel MOS transistor is driven by the internal power supply voltage VDD. Therefore, the ON resistance of the P channel MOS transistor is set higher than the ON resistance of the N channel MOS transistor, and a current driving capacity ratio between the P channel MOS transistor and the N channel MOS transistor increases.

Thus, a problem arises in that when the signal having the power supply voltage VCC amplitude is transitioned from a Hi level to a Lo level or vice versa, the speed of signal inversion decreases.

An object of the present invention is to provide a technique capable of arbitrarily setting a signal state of each I/O terminal thereby to make it possible to prepare an I/O buffer common to products regardless of signal states required for individual product specs.

Another object of the present invention is to provide a technique capable of preparing an I/O buffer suitably adaptable to a change in customer's specs, which is connected to the outside of each individual product.

A further object of the present invention is to provide a technique which arbitrarily sets a signal state of each I/O terminal to thereby enable prevention of a through current of an I/O buffer and a leak test on the I/O buffer.

A still further object of the present invention is to provide a level conversion technique capable of greatly shortening the time required to cause an output signal to transitioned and performing a high-speed operation even in a low voltage.

The above, other objects and novel features of the present invention will become apparent from the description of the present specification and the accompanying drawings.

A summary of a typical one of the inventions disclosed in the present application will be explained in brief as follows:

The present invention provides a semiconductor device comprising I/O buffers which perform input/output control of signals inputted/outputted from and to the outside thereof via I/O terminals, wherein each of the I/O buffers includes a status setting section which arbitrarily sets the I/O terminal to at least either high impedance or signal retention.

Summaries of other inventions of the present application will be described in brief.

The present invention provides a semiconductor device comprising I/O buffer sections which perform input/output control of signals inputted/outputted via I/O terminals (I/O pad), wherein each of the I/O buffer sections includes a signal status setting section which arbitrarily sets the I/O terminal to any of first through third states, wherein the first state set by the signal status setting section indicates that the I/O terminal is brought to a signal holding state which holds the immediately-preceding signal state, and wherein the second state set by the signal status setting section indicates that the I/O terminal is brought to a high impedance state (Hi-z state).

The present invention provides a semiconductor device comprising I/O buffer sections which perform input/output control of signals inputted/outputted via I/O terminals, wherein each of the I/O buffer sections includes a status setting section comprising a status setting register which holds first through third status setting signals, and a status setting circuit which is connected to the corresponding I/O terminal and sets the I/O terminal to an arbitrary state according to a combination of the first through third status setting signals outputted from the status setting register.

Further, in the semiconductor device of the present invention, the status set to the I/O terminal by the status setting circuit comprises any of signal retention, high impedance, pull-up, and pull-down.

There is provided a semiconductor device of the present invention comprising level shifters each of which level-shifts an output signal having a first voltage amplitude outputted from an internal logic circuit to a signal having a second voltage amplitude corresponding to an amplitude larger than the first voltage amplitude and outputs the same therefrom, wherein each of the level shifters comprises a level shift circuit which level-shifts the output signal having the first voltage amplitude to a signal having a second voltage amplitude corresponding to an amplitude greater than the first voltage amplitude, and a level conversion assist section which is provided in the level shift circuit and speeds up transition of the signal having the second voltage amplitude.

Advantageous effects obtained by typical ones of the inventions disclosed in the present application will be explained in brief as follows:

(1) There is provided a status setting section which sets an I/O buffer to an arbitrary signal state. It is thus possible to enhance reliability of a semiconductor device and reduce the cost for design of the semiconductor device.

(2) Since a level conversion assist section is provided in a level shifter, a semiconductor device can be operated at higher speed.

### BRIEF DESCRIPTION OF THE DRAWINGS

FIG. 1 is a block diagram showing a semiconductor device according to one embodiment of the present invention;

FIG. 2 is a block diagram illustrating a configurational example of an I/O buffer section provided in the semiconductor device shown in FIG. 1;

FIG. 3 is a circuit diagram showing a configurational example of a status setting circuit provided in the I/O buffer section shown in FIG. 2;

FIG. 4 is a circuit diagram illustrating a level shifter provided in the semiconductor device shown in FIG. 1;

FIG. 5 is an explanatory diagram showing a layout example of the I/O buffer section shown in FIG. 2;

FIG. 6 is an explanatory diagram illustrating a layout of transistors that constitute an output buffer and the status setting circuit provided in the I/O buffer section shown in FIG. 2;

FIG. 7 is an explanatory diagram showing operating states of the status setting circuit provided in the I/O buffer section shown in FIG. 2;

FIG. 8 is an explanatory diagram showing one example in which ESD protection circuits are provided in an I/O buffer section discussed by the present inventors;

FIG. 9 is an explanatory diagram illustrating one example in which an ESD protection circuit is provided in the I/O buffer section shown in FIG. 2;

FIG. 10 is a timing chart for describing signals at respective parts in the level shifter shown in FIG. 4;

FIG. 11 is a timing chart for describing signals at respective parts, following FIG. 10;

FIG. 12 is an explanatory diagram showing operating states of one example of the status setting circuit provided in the I/O buffer section shown in FIG. 2;

FIG. 13 s an explanatory diagram illustrating operating states of another example of the status setting circuit provided in the I/O buffer section shown in FIG. 2; and

FIG. 14 is a block diagram showing a semiconductor device according to another embodiment of the present invention.

### DETAILED DESCRIPTION OF THE PREFERRED EMBODIMENTS

Preferred embodiments of the present invention will hereinafter be described in detail with reference to the accompanying drawings. In all the drawings for describing the embodiments, the same components or members are given the same reference numerals in principle and their repetitive explanations are therefore omitted.

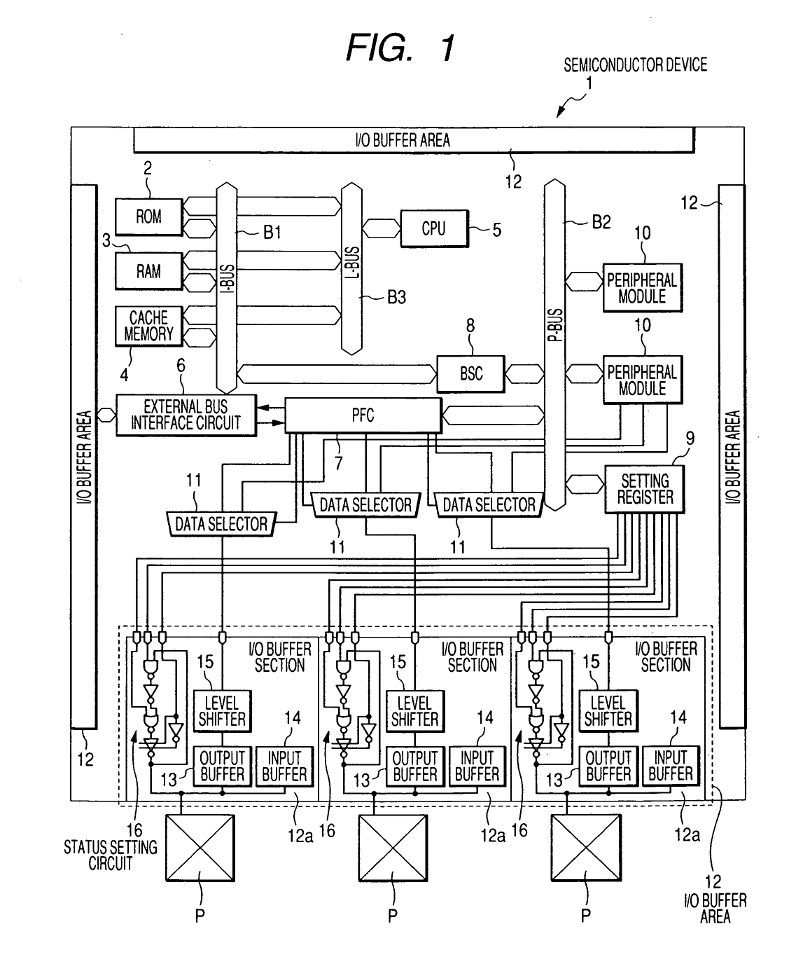

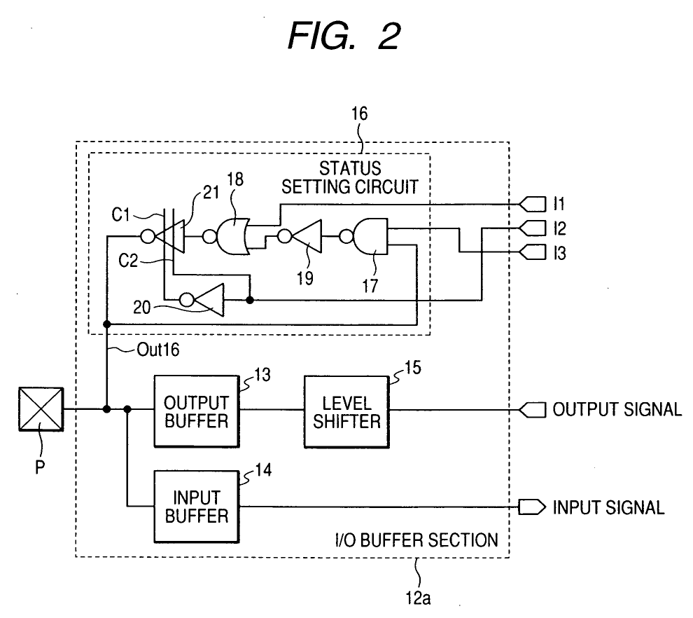

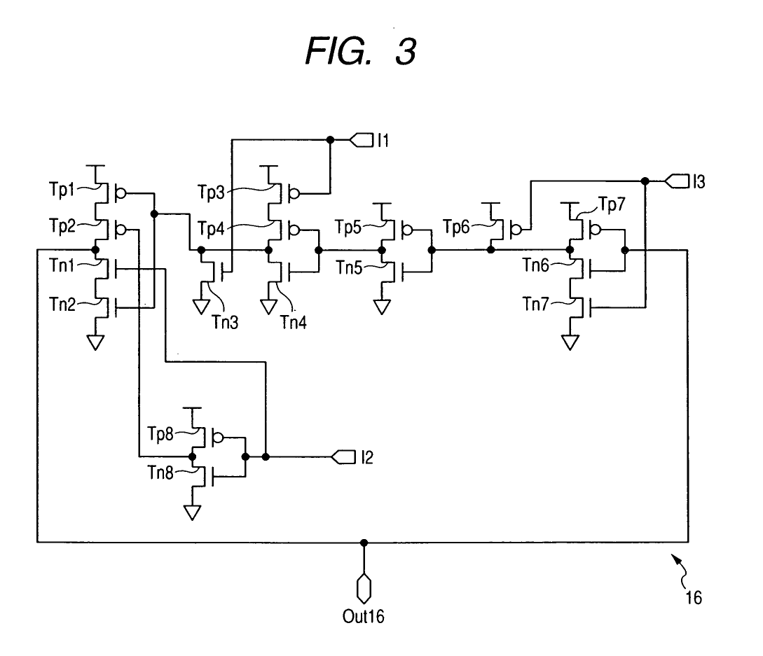

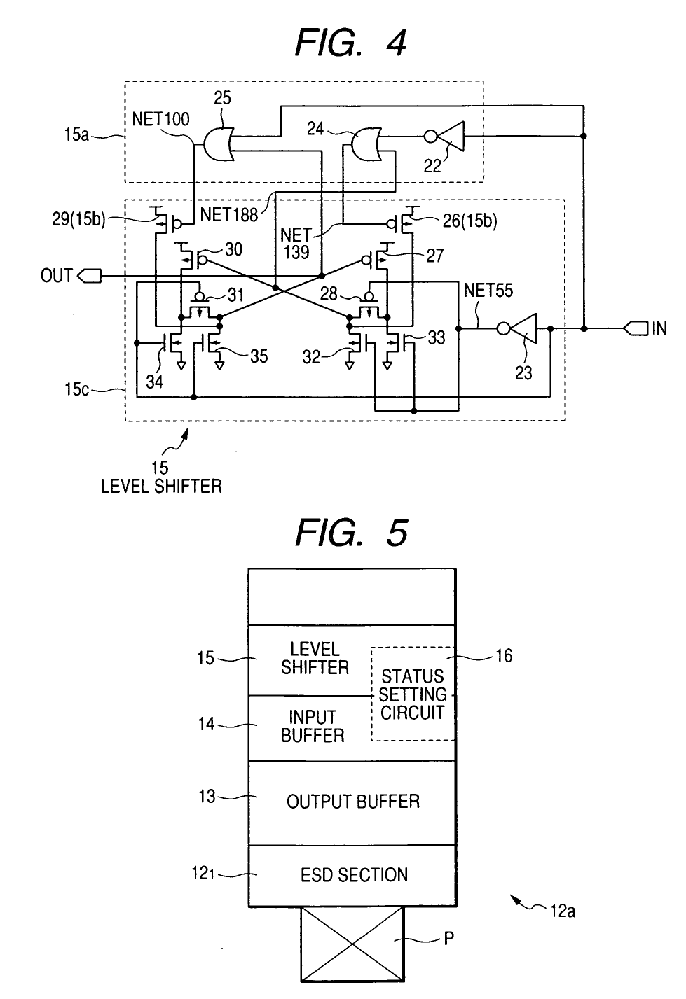

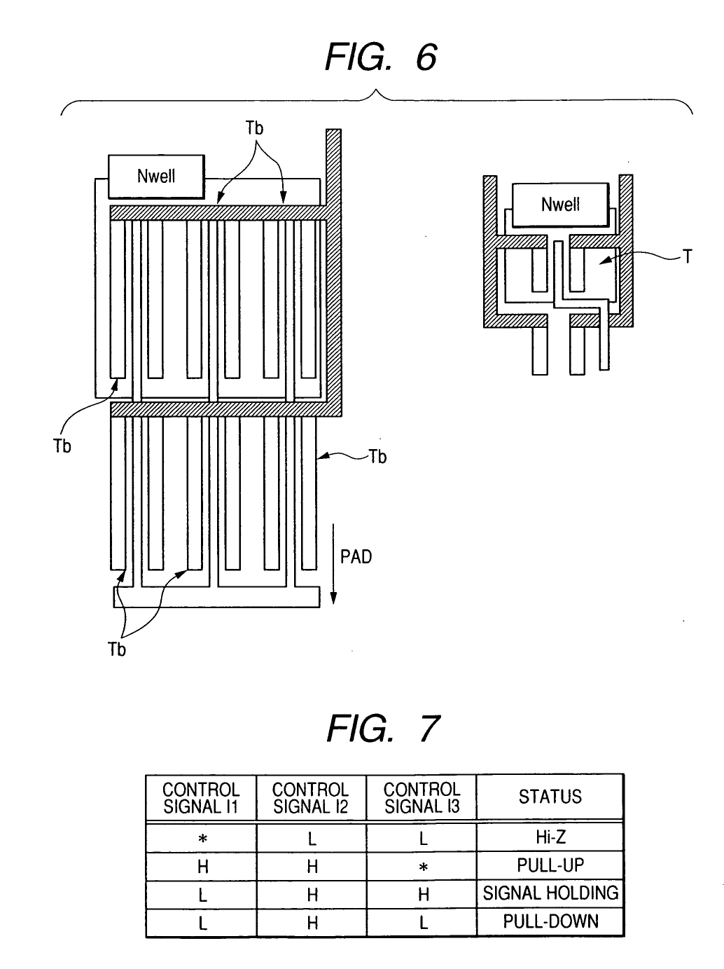

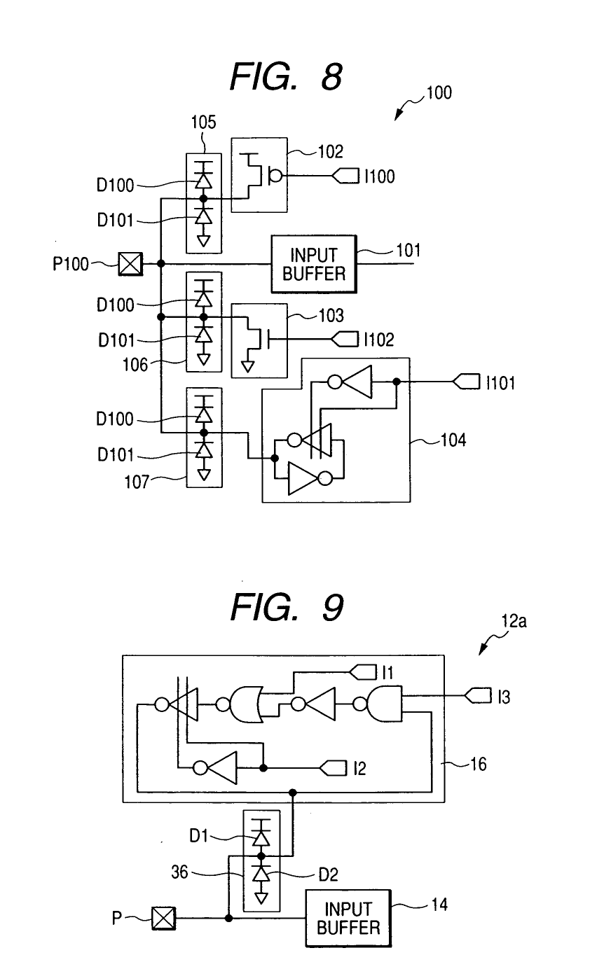

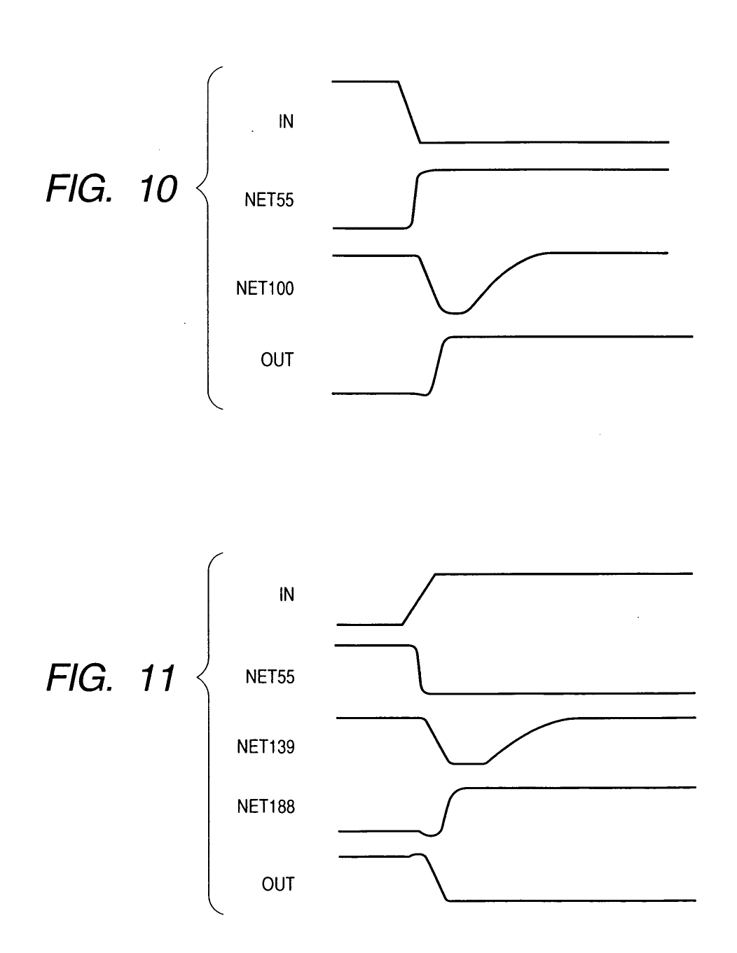

FIG. 1 is a block diagram showing a semiconductor device according to one embodiment of the present invention, FIG. 2 is a block diagram illustrating a configurational example of an I/O buffer section provided in the semiconductor device shown in FIG. 1, FIG. 3 is a circuit diagram showing a configurational example of a status setting circuit provided in the I/O buffer section shown in FIG. 2, FIG. 4 is a circuit diagram illustrating a level shifter provided in the semiconductor device shown in FIG. 1, FIG. 5 is an explanatory diagram showing a layout example of the I/O buffer section shown in FIG. 2, FIG. 6 is an explanatory diagram illustrating a layout of transistors that constitute an output buffer and the status setting circuit provided in the I/O buffer section shown in FIG. 2, FIG. 7 is an explanatory diagram showing operating states of the status setting circuit provided in the I/O buffer section shown in FIG. 2, FIG. 8 is an explanatory diagram showing one example in which ESD protection circuits are provided in an I/O buffer section discussed by the present inventors, FIG. 9 is an explanatory diagram illustrating one example in which an ESD protection circuit is provided in the I/O buffer section shown in FIG. 2, and FIGS. 10 and 11 are timing charts for describing signals at respective parts in the level shifter shown in FIG. 4, respectively.

In the present embodiment, the semiconductor device 1 comprises a single chip microcomputer, for example. As shown in FIG. 1, the semiconductor device 1 comprises a ROM (Read Only Memory) 2, a RAM (Random Access Memory) 3, a cache memory 4, a CPU (Central Processing Unit) 5, an external bus interface circuit 6, a PFC (Pin function Controller) 7, a BSC (Bus State Controller) 8, a setting register (status setting section and status setting register) 9, a peripheral module 10, a plurality of data selectors 11, and I/O buffer areas 12, etc.

The ROM 2 is a nonvolatile memory which stores control programs or the like therein. The RAM 3 is a random readable/writable or accessible volatile memory, which temporarily stores input/output data, operational data, etc. therein.

The cache memory 4 is a memory used to perform a transfer of data between the RAM 3 and the CPU 5. The cache memory 4 stores therein the data stored in the RAM 3. By transferring data between the CPU 5 and the cache memory 4 in this state, the time necessary for access made from the CPU 5 is shortened.

The external bus interface circuit 6 is a circuit for interfacing to an external bus in the semiconductor device 1. The PFC 7 controls the setting of pin functions in the semiconductor device 1.

The BSC 8 controls a transfer of signals among an I-bus (first internal bus) B1, a P-bus (second internal bus) B2, etc. and controls states of the respective buses. The setting register 9 stores control signals (first through third status setting signals) I1 through I3 used to control status setting circuits 16 (see FIG. 2).

The peripheral module 10 may be constituted of a plurality of peripheral modules comprising an MTU (Multi function Timer pulse Unit), an SCIF (Serial Communication Inter Face) and a communication module, etc.

The MTU is a timer which controls motors such as a three-phase motor, a quadri-phase motor, etc., and the SCIF performs communication control of serial data inputted/outputted from and to the outside. The communication module is a LAN (Local Area Network) control module for an automobile system or the like and controls a network intended for communications. Each of the data selectors 11 switches destinations connected to the PFC 7 and the respective modules in the peripheral module 10 depending upon the states of input/output signals under the control of the external bus interface circuit 6.

Each of the I/O buffer areas 12 is provided with a plurality of I/O buffer sections 12a. The I/O buffer section 12a performs input/output control of signals inputted and outputted between the semiconductor device 1 and an external device or the like. The I/O buffer section 12a comprises an output buffer 13, an input buffer 14, a level shifter 15 and a status setting circuit (state setting section) 16.

Also the I/O buffer area 12 is disposed along at least one side of the semiconductor device 1. For example, FIG. 1 shows the I/O buffer areas 12 disposed along the four sides. Further, various internal logic circuits such as the CPU 5, ROM 2, RAM 3, BSC 8, setting register 9, etc. are disposed inside the I/O buffer areas placed along the outer-peripheral four sides of the semiconductor device.

The ROM 2, RAM 3, cache memory 4, BSC 8 and external bus interface circuit 6 are connected to one another via the I-bus B1. The PFC 7, BSC 8, setting register 9 and peripheral module 10 are connected to one another via the P-bus B2. The CPU 5, ROM 2, RAM 3 and cache memory 4 are connected to one another via the L-bus (third internal bus) B3.

The I-bus B1 is a bus which is faster in drive speed (for example, about ½ of the drive speed for the L-bus B3) next to the L-bus B3. The P-bus B2 is a bus to which the peripheral module 10 is connected. The L-bus B3 is a bus which is driven at a speed substantially equal to the CPU 5 or slower than it.

Although not shown in the drawing, a debooster or step-down circuit (regulator, internal step-down circuit), which steps down an external power supply voltage VCC (about 5.0V, for example) supplied from the outside of the semiconductor device to an internal power supply voltage VDD (about 1.5V, for example) for driving each internal logic circuit, is built in the semiconductor device. The level shifter 15 disposed in the I/O buffer section is capable of performing level conversion between an external signal having an external power supply voltage level and an internal signal having an internal power supply voltage level. The internal power supply voltage may be supplied from outside via any of I/O terminals P without generating it inside the semiconductor device.

FIG. 2 is a block diagram showing a configurational example of the I/O buffer section 12a.

The I/O buffer sections 12a are provided every I/O terminals P. The I/O buffer section 12a comprises an ESD section 12, (see FIG. 5) which is a circuit for protection of an electrostatic breakdown, an output buffer 13, an input buffer 14, a level shifter 15 and a status setting circuit 16.

The output buffer 13 performs output control of each signal outputted from the semiconductor device 1 to the external device or the like. The input buffer 14 performs input control of each signal from the outside to the semiconductor device 1.

The level shifter 15 converts an output signal having internal power supply voltage VDD amplitude (first voltage amplitude) outputted from the corresponding internal logic circuit of the semiconductor device 1 to a signal having power supply voltage VCC amplitude (second voltage amplitude).

The I/O terminals P are respectively connected to input parts of the output buffers 13 and output parts of the input buffers 14. An input part of the level shifter 15 is connected to an output part of the output buffer 13.

The data selector 11 is connected to an output part of the level shifter 15, and a logic circuit such as the peripheral module 10 is connected to an input part of the input buffer 14.

The status setting circuit 16 arbitrarily sets the I/O terminal P to which the I/O buffer section 12a is connected, to any of a signal holding state (Weak Keeper), Hi-Z state (High Impedance), a pull-up state, and a pull-down state, based on control signals I1 through I3 stored in the setting register 9.

The status setting circuit 16 comprises a NAND circuit 17, a NOR circuit 18, and inverters 19 through 21. The control signal I3 is connected so as to be inputted to one input of the NAND circuit 17. The I/O terminal P and the output of the inverter 21 are respectively connected to the other input of the NAND circuit 17.

The input of the inverter 19 is connected to its corresponding output of the NAND circuit 17. The other input of the NOR circuit 18 is connected to its corresponding output of the inverter 19. The control signal I1 is connected so as to be inputted to one input of the NOR circuit 18.

The input of the inverter 21 is connected to its corresponding output of the NOR circuit 18. The inverter 21 is provided with control terminals C1 and C2. Output/high impedance (Hi-Z) of a signal connected to the I/O terminal P is controlled according to signals inputted to the control terminals C1 and C2.

The inverter 21 outputs an inverted signal therefrom when a Lo level signal is inputted to the control terminal C1 or a Hi level signal is inputted to the control terminal C2.

The output of the inverter 20 is connected to the control terminal C1 of the inverter 21. The control signal I2 is connected so as to be inputted to the input of the inverter 20 and the control terminal C2 of the inverter 21 respectively.

FIG. 3 is a circuit diagram showing a detailed configuration of the status setting circuit 16.

The status setting circuit 16 comprises transistors Tp1 through Tp8 and transistors Tn1 through Tn8. The inverter 21 is constituted of the transistors Tp1, Tp2, Tn1 and Tn2.

The NOR circuit 18 comprises the transistors Tp3, Tp4, Tn3 and Tn4. The inverter 19 is made up of the transistors Tp5 and Tn5. The NAND circuit 17 is constituted of the transistors Tp6, Tp7, Tn6 and Tn7. The inverter 20 is made up of the transistors Tp8 and Tn8.

The control signals I1 through I3 inputted to the status setting circuit 16 are connected to the respective transistors. An output Out16 of the status setting circuit is connected to the I/O terminal P.

FIG. 4 is a circuit diagram showing the level shifter 15.

The level shifter 15 comprises an assist control section or controller 15a, an output signal assist part 15b and a latch circuit (level shift circuit) 15c. The level shifter 15 is configured as an inverter type which inverts an input signal and outputs it.

The assist controller 15a comprises an inverter 22 and OR circuits 24 and 25. The output signal assist part 15b comprises transistors 26 and 29. The latch circuit 15c comprises transistors 27, 28 and 30 through 35.

Each of the transistors 26 through 31 is made up of a P channel MOS and each of the transistors 32 through 35 is made up of an N channel MOS. Each of the transistors 26 and 29 that constitute the output signal assist part 15b is constituted of a low resistance MOS transistor drivable by a large current.

The output signal assist part 15b assists to speed up the transition of a signal outputted from the level shifter 15 from a Lo level to a Hi level or from the Hi level to the Lo level.

The assist controller 15a controls the operation of the output signal assist part 15b. The latch circuit 15c level-converts an input signal having an amplitude of about 1.5V (internal power supply voltage VDD), for example to an output voltage having an amplitude of about 5.0V (external power supply voltage VCC) and outputs it therefrom.

The signal outputted from the corresponding logic circuit is connected so as to be inputted to the inputs of the inverters 22 and 23, one input of the OR circuit 25 and the gates of the transistor 31 and transistor (fourth transistor) 35. One connecting portion of the OR circuit 24 is connected to the output of the inverter 22.

The gates of the transistors 28, 32 and 33 are respectively connected to the output of the inverter 23. The gate of the transistor (level conversion assist part and second P channel MOS transistor) 26 is connected to the output of the OR circuit 24. The gate of the transistor (level conversion assist part and first P channel MOS transistor) 29 is connected to the output of the OR circuit 25.

A power supply voltage VCC is connected to one connecting portions of the transistors 26, 27, 29 and 30 respectively. One connecting portions of the transistor 28 and transistor (second transistor) 32, the gate of the transistor (third transistor) 30 and the other input of the OR circuit 24 are respectively connected to the other connecting portion of the transistor 26.

The other connecting portion of the transistor 28 and one connecting portion of the transistor 33 are respectively connected to the other connecting portion of the transistor (first transistor) 27. The other connecting portions of the transistors 29 and 31, one connecting portion of the transistor 35 and the other input of the OR circuit 24 are respectively connected to the gate of the transistor 27.

One connecting portions of the transistors 31 and 34 are respectively connected to the other connecting portion of the transistor 30. A reference potential VSS is connected to the other connecting portions of the transistors 32 through 35 respectively. The gate of the transistor 27 serves as the output of the level shifter 15. The output of the level shifter 15 is connected to its corresponding input of the output buffer 13.

FIG. 5 is an explanatory diagram showing a layout example of the I/O output buffer section 12a.

In the I/O buffer section 12a as shown in the drawing, the ESD section 121, the output buffer 13, the input buffer 14 and the level shifter 15 are sequentially disposed toward the corresponding internal logic circuit from the I/O terminal P side.

The output buffer 13 and the input buffer 14 are of transistors driven by, for example, an external power supply voltage. Transistors that constitute the status setting circuit 16 connected thereto are also driven by the external power supply voltage. Thus, the status setting circuit 16 may be placed in the same position as the level shifter 15 driven by the internal power supply voltage and the external power supply voltage or may be positioned on the I/O terminal P side rather than the same position.

Since each of the transistors that constitute the status setting circuit 16 makes use of the same structure as each of the transistors that constitute the output buffer 13, the status setting circuit 16 may be laid out on the internal logic circuit side rather than the ESD section 12₁. For example, the status setting circuit 16 is laid out to a position that extends from the input buffer 14 to the level shifter 15.

FIG. 6 is an explanatory diagram showing the layout of transistors.

In FIG. 6, a layout example of the transistors constituting the output buffer 13 is shown on the right side, whereas a layout example of the transistors that constitute the status setting circuit 16 is shown on the left side.

The transistors Tb that constitute the output buffer 13 are laid out in such a manner that a plurality of transistors T are comb-shaped to enlarge drive capability. The transistors Tb are configured so as to increase in transistor size.

On the other hand, since the status setting circuit 16 may be low in drive capability, there is no need to lay out the plural transistors in comb form as in the transistors that constitute the output buffer 13, and the size of each transistor T can be reduced.

Thus, since the status setting circuit 16 is reduced in transistor size, the degree of freedom of the layout of the status setting circuit 16 can be enhanced.

Since the status setting circuit 16 is reduced in transistor size, it can be placed in any position without increasing the layout size of the I/O buffer section 12a. Further, if the external power supply voltage is supplied, then the position to lay out the status setting circuit 16 is not limited.

The action of the I/O buffer section 12a employed in the present embodiment will next be described.

The operation of the status setting circuit 16 will firstly be explained using an explanatory diagram showing operating states of the status setting circuit 16 based on control signals I1 through I3 shown in FIG. 7.

This control aims to control a signal state at the time that an I/O terminal to be controlled by the status setting circuit 16 does not perform the input/output of a signal. The signal holding state intends to perform the input/output of the signal and hold a signal state prior to the transition to an arbitrary signal state, based on the corresponding control signal.

In order to bring the I/O terminal P to a Hi-Z state, the setting register 9 is first set in such a manner that the control signals I2 and I3 are respectively brought to a Lo level and the control signal I1 is brought to an arbitrary state (* in FIG. 7) as shown in FIG. 7. As to the setting of the setting register 9, for example, bits corresponding to the respective states of the setting register 9 are respectively set from the CPU 5 via the internal buses (L-bus B3, I-bus B1 and P-bus B2). Alternatively, the respective bits for the setting register may be set directly from the CPU 5 using dedicated control lines.

When a signal of a Lo level is inputted to the inverter 20, the control terminal C2 of the inverter 21 and one input of the NAND circuit 17 respectively, a signal of a Hi level is inputted to the control terminal C1 of the inverter 21 and a signal of a Lo level is inputted to the control terminal C2 respectively. Thus, since the inverter 21 is brought to a Hi-Z state, the I/O terminal P is brought to the Hi-Z state.

When the I/O terminal P is then set to a pull-up state, the setting register 9 is set in such a manner that the control signals I1 and I2 are respectively brought to the Hi level and the control signal I3 is brought to the arbitrary state (* in FIG. 7) as shown in FIG. 7.

When the control signal I1 of the Hi level is inputted, the NOR circuit 18 outputs a signal of a Lo level. Since the Lo level and Hi level signals are respectively inputted to the control terminals C1 and C2 of the inverter 21, an inverted signal of the input signal (Lo level) is outputted from the output of the inverter 21. Thus, the I/O terminal P becomes a Hi level, i.e., the pull-up state.

When the I/O terminal P is set to the signal holding state, the setting register 9 is set in such a manner that as shown in FIG. 7, the control signal I1 is brought to the Lo level and the control signals 12 and 13 are respectively brought to the Hi level. Here, the status of the I/O terminal P is set assuming that a signal A has been outputted.

When the control signal I3 of the Hi level is inputted to one input of the NAND circuit 17, the NAND circuit 17 outputs an inverted signal /A of the signal A. Since the inverted signal /A and the control signal I1 of the Lo level are respectively inputted to the input of the NOR circuit 18, the signal /A is outputted to the inverter 21.

Since the control signal I2 of the Hi level and the signal of the Lo level inverted by the inverter 20 are respectively inputted to the control terminals C1 and C2 of the inverter 21, the signal A corresponding to an inverted signal of the inverted signal /A is outputted from the inverter 21, so that the signal state of the I/O terminal P is held.

Further, in order to bring the I/O terminal P to a pull-down state, the setting register 9 is set in such a manner that as shown in FIG. 7, the control signals I1 and I3 are brought to the Lo level and the control signal I2 is brought to the Hi level.

When the control signal I3 of the Lo level is inputted, the NAND circuit 17 outputs a signal of a Hi level. The control signal I1 of the Lo level and the output signal (Lo level) of the NAND circuit 17, which is inverted by the inverter 19, are respectively inputted to the inputs of the NOR circuit 18. A signal of a Hi level is outputted from the output of the NOR circuit 18.

Since the control signal I2 of the Hi level and the Lo level signal corresponding to the inverted signal of the inverter 20 are respectively inputted to the control terminals C1 and C2 of the inverter 21, the inverted signal of the Hi level outputted from the NOR circuit 18 is outputted from the output of the inverter 21. Thus, the I/O terminal P is brought to the Lo level, i.e., the pull-down state.

By providing the status setting circuit 16 in this way, the I/O terminal P can arbitrarily be selected and set to any of the pull-up state, pull-down state, and signal holding state. Therefore, there is no need to individually provide a pull-up circuit for setting the pull-up state, a pull-down circuit for setting the pull-down state or a signal holding circuit for setting the signal holding state, or the like for each I/O buffer section. It is thus possible to reduce the cost for design of the I/O buffer section 12a.

Further, the plurality of signal states can be set by one status setting circuit. Consequently, the multifunctional I/O terminals can be provided in the I/O buffer area without increasing a layout size.

The setting register may take such a configuration as to be able to set the states set to the plural I/O terminals every I/O terminals. Alternatively, it may take such a configuration as to be capable of collectively setting the plural I/O terminals.

In the semiconductor device 1, a screening test and the like include a leak test for testing whether the I/O buffer section 12a is good. Upon the leak test, the I/O buffer section 12a is brought to a Hi-Z state, and the power supply voltage VCC or reference potential VSS is applied to the corresponding I/O terminal P. It is then confirmed whether a current flows.

Upon the leak test, the current flows where the I/O terminal P is set to the signal holding state. However, the leak test on the I/O buffer section 12a can be performed by causing the status setting circuit 16 to temporarily set the I/O buffer section 12a to the Hi-Z state upon testing.

FIG. 8 is an explanatory diagram showing one example in which ESD (Electrostatic Discharge) protection circuits are provided in a conventional I/O buffer section 100 discussed by the present inventors. FIG. 9 is an explanatory diagram showing one example in which an ESD protection circuit is provided in the I/O buffer section 12a employed in the present embodiment.

In FIG. 8, an output buffer and a level shifter of the I/O buffer section 100 are respectively omitted for simplification. Even in FIG. 9 in a manner similar to above, the output buffer 13 (see FIG. 2) and level shifter 15 (see FIG. 2) of the I/O buffer section 12a are respectively omitted.

As shown in FIG. 8, the I/O buffer section 100 comprises an input buffer 101, a pull-up circuit 102, a pull-down circuit 103, a signal holding circuit 104, an output buffer and a level shifter. The I/O buffer section 100 has the function of being capable of arbitrarily setting an I/O terminal P100 to any of a pull-up state, a pull-down state, and a signal holding state.

The I/O terminal P100 is connected to the input of the input buffer 101, the pull-up circuit 102, the pull-down circuit 103 and the signal holding circuit 104.

The pull-up circuit 102 is a circuit for bringing the I/O terminal P100 to the pull-up state and comprises a P channel MOS transistor, for example. A power supply voltage VCC is connected to one connecting portion of the transistor, whereas the I/O terminal P100 is connected to the other connecting portion of the transistor.

A control signal I100 is connected so as to be inputted to the gate of the transistor. When the control signal I100 is brought to a Lo level, the transistor is turned ON to bring the I/O terminal P100 to the pull-up state.

The pull-down circuit 103 is a circuit for bringing the I/O terminal P100 to the pull-down state and comprises an N channel MOS transistor. The I/O terminal P100 is connected to one connecting portion of the transistor, whereas a reference potential VSS is connected to the other connecting portion thereof.

A control signal I101 is connected so as to be inputted to the gate of the transistor. When the control signal I101 is brought to a Lo level, the transistor is turned ON to bring the I/O terminal P100 to the pull-down state.

The signal holding circuit 104 is a circuit for holding a signal state of the I/O terminal P100 and comprises an inverter and a latch circuit. The signal holding circuit 104 latches the signal state of the I/O terminal P100 on the basis of a control signal I102 inputted to the latch circuit and an inverted signal of the control signal I102 inputted via the inverter.

When the I/O buffer section 100 having such a configuration is provided with circuits for ESD protection, a plurality of ESD protection circuits 105 through 107 are required to prevent the respective circuits of the pull-up circuit 102, pull-down circuit 103 and signal holding circuit 104 from device breaking down due to electrostatic discharge (ESD).

Each of the ESD protection circuits 105 (through 107) comprises, for example, two diodes D100 and D101. A cathode of the diode D100 is connected to the power supply voltage VCC, and an anode of the diode D101 is connected to the reference potential VSS. An anode of the diode D100 and a cathode of the diode D101 are connected to the I/O terminal P100.

Thus, in order to realize the setting of a plurality of signal states to one I/O terminal, there is a need to dispose the respective circuits and the ESD protection circuits, thereby causing an increase in layout size.

Incidentally, the input buffer and output buffer of the I/O buffer section 100 also need ESD protection circuits in practice. However, they are omitted for simplification of comparison.

On the other hand, when the I/O buffer section 12a is provided with a circuit for ESD protection, a status setting circuit 16 that arbitrarily selects and sets any of a pull-up state, a pull-down state, a Hi-Z state, and a signal holding state is provided with an ESD protection circuit 36 as shown in FIG. 9. While ESD protection circuits are necessary even for an input buffer 14 and an output buffer 13 in practice even in FIG. 9, they are omitted for simplification of comparison.

The ESD protection circuit 36 comprises two diodes D1 and D2 in a manner similar to the ESD protection circuits 105 through 107 of the I/O buffer section 100. A cathode of the diode D1 is connected to a power supply voltage VCC and an anode of the diode D2 is connected to a reference potential VSS, respectively. An anode of the diode D1 and a cathode of the diode D2 are respectively connected to an I/O terminal P.

Thus, although the three ESD protection circuits are necessary for the I/O buffer section 100 discussed by the present inventors, in which the pull-up circuit 102, pull-down circuit 103 and signal holding circuit 104 shown in FIG. 8 are individually provided, only one ESD protection circuit connected to the status setting circuit 16 may be provided in the I/O buffer section 12a employed in the present embodiment shown in FIG. 9. It is therefore possible to greatly reduce a layout area for a semiconductor chip.

In order to reduce the layout area, any of the pull-up circuit 102, the pull-down circuit 103 and the signal holding circuit 104 is provided in the I/O buffer section 100 according to settings. In such a case, however, there is a need to prepare three types of I/O buffer sections. Thus, the cost for development of those I/O buffer sections and the cost for design of a semiconductor device at the time that the I/O buffer sections change in specs increase.

Since, however, only one I/O buffer section 12a may be prepared, the I/O buffer section 12a provided with the status setting circuit 16 can be reduced in design cost. Even in the case of changes in the external specs of the semiconductor device, only a change in set value of the status setting circuit makes it possible to easily adapt to a change in its I/O terminal function, thereby making it possible to lead to shortening of a design period.

The operation of the level shifter 15 will next be explained using timing charts shown in FIGS. 10 and 11.

Signal timings provided for an input signal IN inputted to the level shifter 15, an output signal NET55 of the inverter 23, an output signal NET100 of the OR circuit 25 and an output signal OUT of the level shifter 15 are respectively shown in FIG. 10 from above to below.

Signal timings provided for an input signal IN inputted to the level shifter 15, an output signal NET55 of the inverter 23, an output signal NET139 of the OR circuit 24, a signal NET188 inputted to the gate of the transistor 30, and an output signal OUT of the level shifter 15 are respectively shown in FIG. 11 from above to below.

When the input signal IN is first transitioned from a Hi level to a Lo level in FIG. 10, a Lo level signal is inputted to one connecting portion of the OR circuit 25. Since the output signal OUT is held at the Lo level at the moment of transition of the input signal IN from the Hi level to the Lo level, the signal of the Lo level is inputted even to the other connecting portion of the OR circuit 25, so that the output signal NET100 of the OR circuit 25 changes from a Hi level to a Lo level.

The transistors 32 and 33 are turned ON by a Hi level signal outputted via the inverter 23, so that a Lo level signal is inputted to the gate of the transistor 30 to turn ON the transistor 30.

When the output signal NET100 is brought to a Lo level, the transistor 29 is turned ON. Since the transistor 29 is of a large current-driven transistor, the output signal OUT is rapidly transitioned to a Hi level and outputted.

When the output signal OUT reaches the Hi level, the signal NET100 outputted from the OR circuit 25 is transitioned from a Lo level to a Hi level to turn OFF the transistor 29. Thus, the output assist of the output signal OUT by the transistor 29 is terminated.

In FIG. 11, the signal NET188 becomes a Lo level at the moment that the input signal IN is transitioned from the Lo level to the Hi level. Thus, a Lo level signal is inputted via the inverter 22 to one input of the OR circuit 24, whereas the signal NET188 of the Lo level is inputted to the other input of the OR circuit 24.

Thus, the signal NET139 of the Lo level is outputted from the OR circuit 24 to turn ON the transistor 26, so that the signal NET188 can be rendered a Hi level in a short period of time. Consequently, the transistor 30 can be turned OFF in a short period of time and the output signal OUT can be transitioned to the Lo level in a short period of time.

Consequently, even though the ratio of level-shift voltages increases and a current driving capacity ratio between each of the p channel MOS transistors and each of the N channel MOS transistors that constitute the latch circuit 15c increases, the time necessary for the rising edge/falling edge of the output signal OUT can be shortened, and the I/O buffer section 12a can be operated at high speed. Since the transistors 26 and 29 that constitute the output signal assist section 15a are held OFF except for at the output assist of the output signal OUT, current consumption can be reduced.

Thus, according to the present embodiment, the design cost of the semiconductor device 1 can be cut down owing to the provision of the status setting circuit 16, and the layout area of the semiconductor device can be reduced.

Since the operating speed of the level shifter 15 can be made fast, the performance of the semiconductor device 1 can be enhanced.

Further, in the present embodiment, the I/O terminal P connected with the I/O buffer section 12a is arbitrarily set to any of the pull-up state, pull-down state, signal holding state, and Hi-Z on the basis of the control signals I1 through I3 stored in the setting register 9. However, for example, registers are provided for each port and the status of the status setting circuit 16 may be arbitrarily changed. Here, the port indicates a group comprising the plural I/O buffer sections 12a each having the same function.

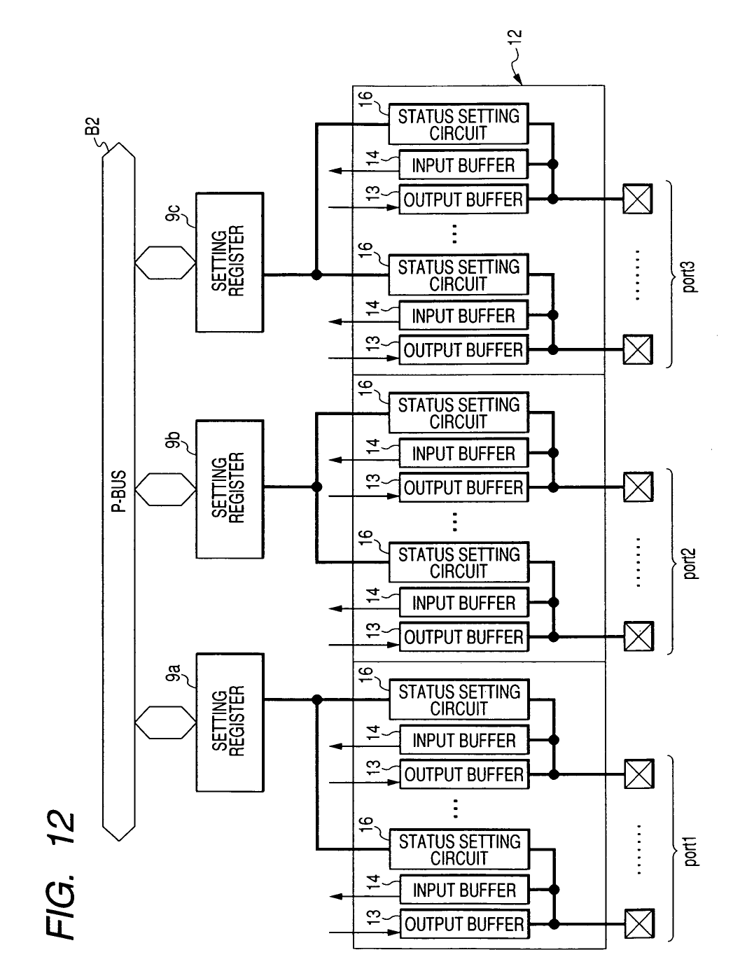

FIG. 12 is an explanatory diagram showing one example in which the states of status setting circuits 16 are arbitrarily changed every ports. A plurality of I/O terminals each having the same function are called “port Port”.

When, for example, three groups of ports Port1 through Port3 are provided, the ports Port1 through Port3 are respectively provided with setting registers 9a through 9c one by one. These setting registers 9a through 9c are connected to their corresponding status setting circuits 16 provided in the ports Port1 through Port3.

Control signals I1 through I3 of the respective setting registers 9a through 9c are set to a mode controller or the like provided in a semiconductor device. Consequently, the states of the status setting circuits 16 can arbitrarily be changed collectively with respect to the I/O terminals P included every ports Port1 through Port3. Alternatively, arbitrary signal states can be set every ports by allowing a CPU to set values to the respective setting registers 9a through 9c via a P-bus B2.

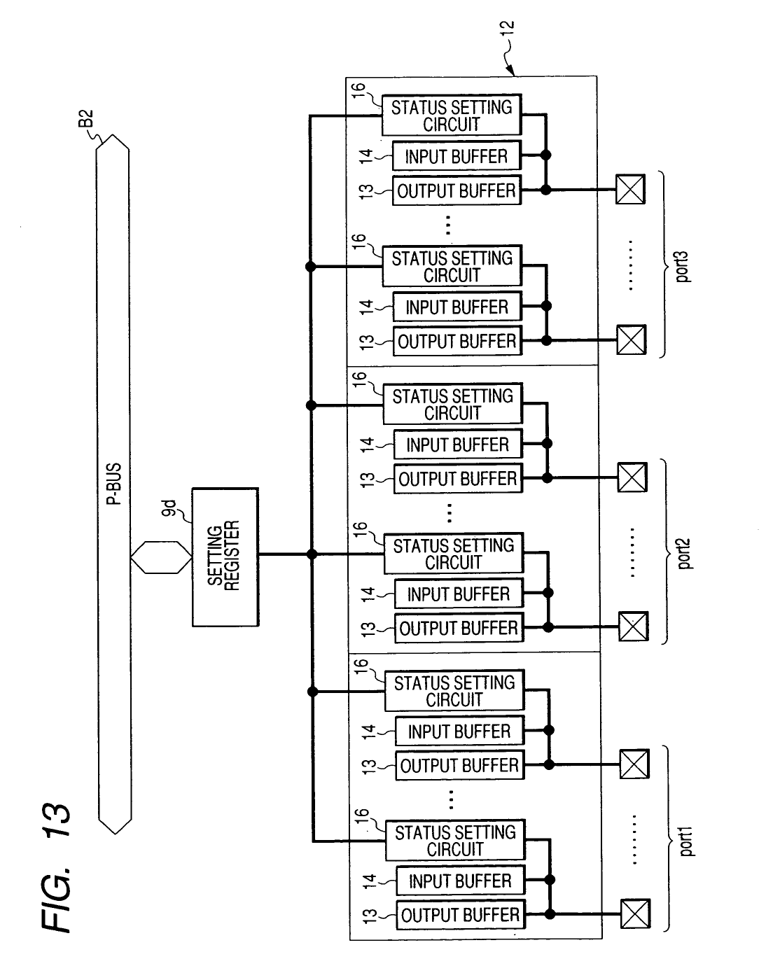

All ports Port1 through Port3 may collectively be changed to the same state as shown in FIG. 13, for example without arbitrarily changing the states of the status setting circuits 16 collectively every ports Port1 through Port3 respectively.

In this case, it can be realized by providing a setting register 9d and connecting control signals I1 through 13 stored in the setting register 9d so as to be inputted to the status setting circuits 16 provided in all the ports Port1 through Port3.

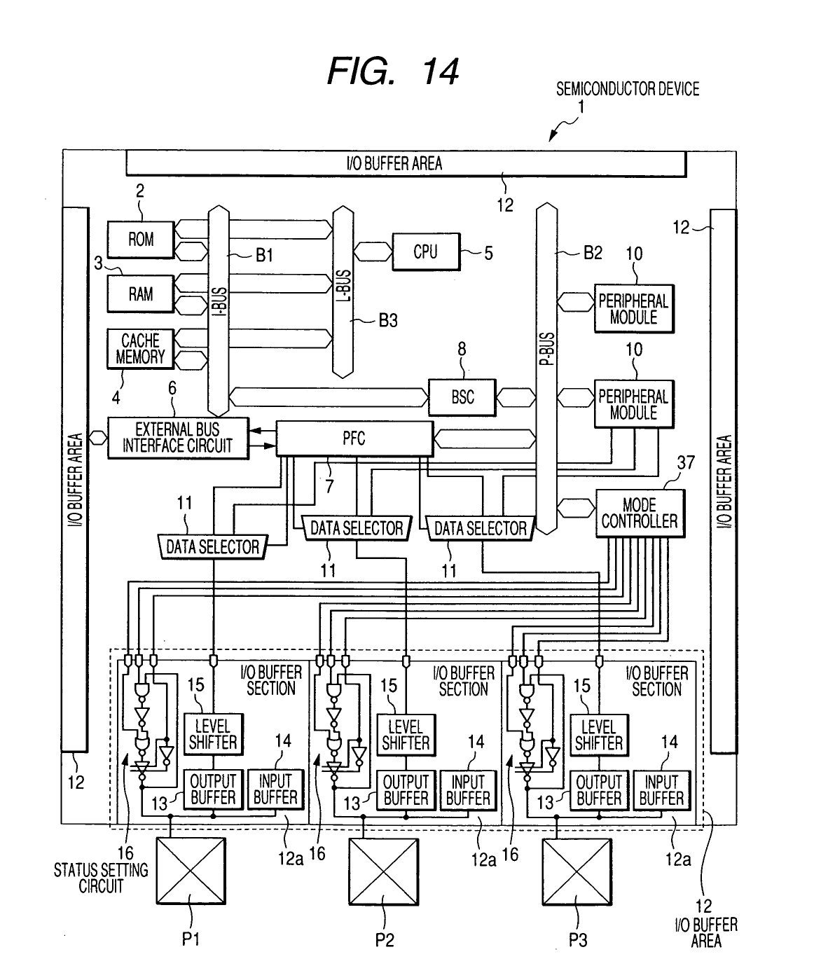

FIG. 14 is a block diagram showing one example in which states (signal holding state, Hi-Z, pull-up state or pull-down state) of respective terminals are arbitrarily set according to operating modes of a semiconductor device 1.

In this case, the semiconductor device 1 is provided with a mode controller 37 which sets operating modes (e.g., switching of ON/OFF of PLL, standby state of CPU5 and the like, setting of effective address, etc.) or the like of the semiconductor device 1 according to settings of external terminals.

A status setting circuit 16 connected to a mode terminal P1 corresponding to a terminal for determining the operating mode of the semiconductor device 1 shown in FIG. 14 is set to the pull-up state at the mode terminal P1, whereby the semiconductor device 1 can be set to a certain state.

Setting the status setting circuit 16 connected to the mode terminal P1 to the pull-down state in a manner similar to above makes it possible to set the semiconductor device 1 to another state.

An AUD terminal P2 corresponding to one of test terminals shown in FIG. 14 is normally expected to have an input of a Lo level or a Hi level. However, there is a fear that when an electrical level of each terminal becomes an instable state immediately after power-on of the semiconductor device 1, for example, this action interferes with the operation of the semiconductor device 1.

Therefore, the status setting circuit 16 connected to the AUD terminal P2 is set to an arbitrary state to thereby make it possible to prevent a failure in operation or the like of the semiconductor device 1.

Floating of a system terminal P3 constituted of a general-purpose I/O or the like presents a problem for the system terminal P3. However, its floating can be prevented by setting the corresponding status setting circuit 16 connected to the system terminal P3 to an arbitrary state so as to prevent its floating.

While the invention made above by the present inventors has been described specifically on the basis of the preferred embodiments, the present invention is not limited to the embodiments referred to above. It is needless to say that various changes can be made thereto without the scope not departing from the gist thereof.

Owing to the provision of such a configuration that a signal state of each I/O terminal is arbitrarily set, the semiconductor device of the present invention is suitable for a technique for providing facilitation of a change in design of the I/O terminal and speeding-up of the operation of a level shifter.

1. A semiconductor device comprising:
I/O buffers which perform input/output control of signals inputted/outputted via I/O terminals,
wherein each of the I/O buffers includes a status setting section which arbitrarily sets the I/O terminal to at least either high impedance or signal holding.

2. A semiconductor device comprising:
I/O buffer sections which perform input/output control of signals inputted/outputted via I/O terminals,
wherein each of the I/O buffer sections includes a status setting section which arbitrarily sets the I/O terminal to any of first to third signal states,
wherein the first signal state set by the status setting section indicates that the I/O terminal is brought to a signal holding state, and
wherein the second signal state set by the status setting section indicates that the I/O terminal is brought to a high impedance state.

3. The semiconductor device according to claim 2, wherein the third signal state set by the status setting section indicates that the I/O terminal is brought to a pull-up state.

4. The semiconductor device according to claim 2, wherein the third signal state set by the status setting section indicates that the I/O terminal is brought to a pull-down state.

5. A semiconductor device comprising:
I/O buffer sections which perform input/output control of signals inputted/outputted via I/O terminals,
wherein each of the I/O buffer sections includes,
a status setting section comprising:
a status setting register which holds first through third status setting signals; and
a status setting circuit which is connected to the corresponding I/O terminal and sets the I/O terminal to an arbitrary state according to a combination of the first to third status setting signals outputted from the status setting register.

6. The semiconductor device according to claim 5, wherein the status set to the I/O terminal by the status setting circuit comprises either pull-up, pull-down, high impedance or signal holding.

7. The semiconductor device according to claim 5, further comprising:
internal logic circuits including a central processing unit, capable of setting the status signal to each of the status setting registers,
wherein each of the I/O buffer sections includes:
an output buffer which performs output control of a signal outputted to the outside;
an input buffer which performs input control of a signal inputted from outside; and
an electrostatic breakdown protection section which performs electrostatic breakdown protection for the output buffer, the input buffer and the status setting circuit, and
wherein the status setting circuit is laid out on the internal logic circuit side than the electrostatic breakdown protection section.

8. The semiconductor device according to claim 7, wherein each of the status setting circuits is supplied with a voltage substantially identical to an operating voltage of the output buffer.

9. The semiconductor device according to claim 7,
wherein the status setting registers are provided every ports each comprising a plurality of the I/O terminals each having the same function, and
wherein the central processing unit is capable of collectively setting the ports to an arbitrary state respectively by individually setting the status setting registers provided every ports.

10. The semiconductor device according to claim 7, wherein each of the status setting registers is set in such a manner that an arbitrary combination of the first through third status setting signals is outputted by the central processing unit.

11. A semiconductor device comprising:
input/output buffers which control signals inputted/outputted via a plurality of input/output terminals,
wherein each of the input/output buffers includes:
a first input/output terminal;
a second input/output terminal;
a first control circuit connected to the first input/output terminal, for controlling a signal state of the first input/output terminal; and
a second control circuit connected to the second input/output terminal, for controlling a signal state of the second input/output terminal,
wherein the first and second control circuits are capable of setting the signal states to at least either high impedance or signal retention.

12. The semiconductor device according to claim 11, wherein the first and second control circuits are further capable of setting the signal states to either a pull-up state or a pull-down state.

13. A semiconductor device comprising:
level shifters each of which level-shifts an output signal having a first voltage amplitude outputted from an internal logic circuit to a signal having a second voltage amplitude corresponding to an amplitude larger than the first voltage amplitude and outputs the same therefrom,
wherein each of the level shifters includes:
a level shift circuit which level-shifts the output signal having the first voltage amplitude to a signal having a second voltage amplitude corresponding to an amplitude greater than the first voltage amplitude; and
a level conversion assist section which is provided in the level shift circuit and speeds up transition of the signal having the second voltage amplitude.

14. The semiconductor device according to claim 13,
wherein the level shift circuit comprises a first inverter having a configuration in which a first transistor and a second transistor are connected in series, and a second inverter having a configuration in which a third transistor and a fourth transistor are connected in series, and has a configuration in which a gate of the first transistor and one connecting portion of the fourth transistor, and a gate of the third transistor and one connecting portion of the second transistor are respectively connected in crossed form, and
wherein the level conversion assist section comprises:
a first P channel MOS transistor of which one connecting portion is connected to a power supply voltage and the other connecting portion is connected to one connecting portion of the second transistor, and
a second P channel MOS transistor of which one connecting portion is connected to the power supply voltage and the other connecting portion is connected to one connecting portion of the fourth transistor.
